(19) United States
(12) Patent Application Publication
(10) Pub. No.: US 2023/0282627 A1
(43) Pub. Date: Sep. 7, 2023

(54) SEMICONDUCTOR MEMORY DIES BONDED TO LOGIC DIES AND ASSOCIATED SYSTEMS AND METHODS

(71) Applicant: Micron Technology, Inc., Boise, ID (US)

(72) Inventors: Kunal R. Parekh, Boise, ID (US); Hernan A. Castro, Shingle Springs, CA (US)

(21) Appl. No.: 18/111,266

(22) Filed: Feb. 17, 2023

Related U.S. Application Data
(60) Provisional application No. 63/315,789, filed on Mar. 2, 2022.

(51) Int. Cl. H01L 25/16; H01L 23/00; H10B 80/00; H01L 21/66; G06N 3/063; H01L 21/324; H01L 21/3105; H01L 21/321

(52) U.S. Cl. CPC H01L 25/16; G06N 3/063; H01L 21/3105; H01L 21/321; H01L 21/324; H01L 22/32; H01L 24/08; H01L 24/16; H01L 24/48; H01L 24/80; H10B 80/00; H01L 2224/08145; H01L 2224/16225; H01L 2224/48227; H01L 2224/80895; H01L 2224/80896; H01L 2224/80948; H01L 2924/1011; H01L 2924/1431; H01L 2924/1438

(57) ABSTRACT

Semiconductor memory dies bonded to logic dies and associated systems and methods are disclosed. In an embodiment, a semiconductor die assembly includes a logic die and one or more memory dies directly bonded to the logic die. The logic die includes integrated circuits generated using relatively high temperature process steps whereas the memory dies include memory cells with materials generated using relatively low temperature process steps. The logic die and the memory dies have been separately fabricated in two different wafers such that process steps generating them can be optimized independently of each other. The resulting semiconductor device including the memory dies bonded to the logic die functions as a single device as if they were formed in a monolithic substrate. The resulting semiconductor device may be configured to perform artificial intelligence tasks.

### CROSS-REFERENCE TO RELATED APPLICATIONS

The present application claims priority to U.S. Provisional Pat. Application No. 63/315,789, filed Mar. 2, 2022, the disclosure of which is incorporated herein by reference in its entirety.

This application contains subject matter related to a U.S. Provisional Pat. Application by Hernan A. Castro et al. titled “SEMICONDUCTOR DIE STACKS AND ASSOCIATED SYSTEMS AND METHODS.” The related application is assigned to Micron Technology, Inc., and is identified as U.S. Provisional Pat. Application No. 63/315,809, filed on Mar. 2, 2022. The subject matter thereof is incorporated herein by reference thereto.

### TECHNICAL FIELD

The present disclosure generally relates to semiconductor device assemblies, and more particularly relates to semiconductor memory dies bonded to logic dies and associated systems and methods.

### BACKGROUND

Semiconductor packages typically include one or more semiconductor dies (e.g., memory chips, microprocessor chip, imager chip) mounted on a package substrate and encased in a protective covering. The semiconductor die may include functional features, such as memory cells, processor circuits, or imager devices, as well as bond pads electrically connected to the functional features. The bond pads can be electrically connected to corresponding conductive structures of the package substrate, which may be coupled to terminals outside the protective covering such that the semiconductor die can be connected to higher level circuitry.

In some semiconductor packages, two or more semiconductor dies are stacked on top of each other to reduce the footprint of the semiconductor packages. The semiconductor dies in the stack may be arranged in a pattern resembling stair-steps (which may be referred to as “shingle stacking”) such that a portion of the semiconductor dies may be freely accessible – e.g., to attach bond wires to one or more bond pads located in the portion. In some cases, the semiconductor dies may be stacked in a “zig-zag” pattern to increase a space above the bond pads with respect to a semiconductor die overlying above the bond pads so as to facilitate forming the bond wires. Such arrangements, however, tend to increase overall heights of the semiconductor packages. Further, the bond wires may add to the heights and/or introduce delays in signal propagation.

### BRIEF DESCRIPTION OF THE DRAWINGS

Many aspects of the present technology can be better understood with reference to the following drawings. The components in the drawings are not necessarily to scale. Instead, emphasis is placed on clearly illustrating the overall features and the principles of the present technology.

FIG. 1 illustrates various stages of process steps for direct bonding schemes.

FIG. 2 is a diagram of a substrate carrying semiconductor dies in accordance with embodiments of the present technology.

FIGS. 3A through 3C illustrate example schematic diagrams depicting various stages of forming semiconductor die assemblies in accordance with embodiments of the present technology.

FIG. 4 illustrates schematic diagrams depicting various stages of forming semiconductor die assemblies in accordance with embodiments of the present technology.

FIG. 5 illustrates schematic diagrams depicting various stages of forming semiconductor die assemblies in accordance with embodiments of the present technology.

FIG. 6 is a block diagram schematically illustrating a system including a semiconductor die assembly in accordance with embodiments of the present technology.

FIG. 7 is a flowchart of a method of forming semiconductor die assemblies in accordance with embodiments of the present technology.

### DETAILED DESCRIPTION

Specific details of several embodiments of semiconductor memory dies bonded to logic dies for semiconductor die assemblies, and associated systems and methods are described below. The term “semiconductor device or die” generally refers to a solid-state device that includes one or more semiconductor materials. Examples of semiconductor devices (or dies) include logic devices or dies, memory devices or dies, controllers, or processors (e.g., central processing unit (CPU), graphics processing unit (GPU)), among others. The semiconductor devices may include integrated circuits or components, data storage elements (memory cells), information processing components, and/or other features manufactured on semiconductor substrates.

Further, the term “semiconductor device or die” can refer to a finished device or to an assembly or other structure at various stages of processing before becoming a finished functional device. Depending upon the context in which it is used, the term “substrate” may include a semiconductor wafer, a package substrate, a semiconductor device or die, or the like. Suitable steps of the methods described herein can be performed with processing steps associated with fabricating semiconductor devices (wafer-level and/or die-level) and/or manufacturing semiconductor packages.

Semiconductor process technology generally includes wide variety of process steps, process conditions, and materials for generating semiconductor devices. Certain structures of the device (e.g., logic circuits configured to performing a variety of logic functions) are fabricated using process steps with relatively high temperature – e.g., approximately 600° C. (°C) or higher. For example, the logic circuits may include a silicide, an epitaxial layer, or a semiconductor junction with a junction depth greater than 0.1 micrometers (µm), those which require process steps with temperature ranging from approximately 600° C. to 1000° C. or even higher.

On the other hand, certain structures of the devices (e.g., memory cells configured to store information) are fabricated using process steps with relatively low temperature – e.g., typically less than 600° C. For example, phase change memory (PCM) cells may include a chalcogenide compound formed at around 400° C. as a data storage structure. Cell capacitors of dynamic random access memory (DRAM) cells may include a high-k dielectric material with a dielectric constant greater than that of silicon dioxide (SiO₂), which are typically formed below 600° C. Also, Not-AND (NAND) memory cells may include the high-k dielectric material as a charge retention layer (e.g., a charge trapping layer) or as an interface material (e.g., an inter-polysilicon dielectric (IPD) layer). The high-k dielectric material may include an oxide or a silicate having one of aluminum, hafnium, zirconium, or lanthanum, among others.

The foregoing materials (low-temperature regime materials) formed at the relatively low temperature play critical roles for the memory cells but tend to lose their desired characteristics if they are subject to the relatively high temperature described above. In some instances, fundamental physical characteristics of the low-temperature regime materials can be destroyed upon receiving the thermal energy associated with the high temperature process steps – e.g., the chalcogenide compound no longer switching back-and-forth between low and high resistance states.

In other instances, the desired physical characteristics of the low-temperature regime materials may be deteriorated upon receiving the thermal energy due to interactions with other materials – e.g., the high-k dielectric materials intermixed with adjacent materials resulting in reduced dielectric constant values. In some cases, if the low-temperature regime materials experience the relatively high temperature, the memory cells may become non-functional. In other cases, the memory cell characteristics may deteriorate upon having their low-temperature regime materials experiencing the relatively high temperature – e.g., the memory cells with shortened charge/data retention, degraded cycling performance, increased disturb behavior, among others.

Consequently, if the logic circuits and the memory cells were to be integrated on a single substrate (or a single wafer), the temperature sensitivity of the memory cell materials would require the logic circuits to be completed prior to forming the memory cells so as to avoid adverse effects of the process steps done at the relatively high temperature. Such requirements restrict the overall integration schemes for optimizing performance of the logic circuits and the memory cells independent of each other.

It would be desirable to fabricate semiconductor devices separately in two or more temperature regimes such that process conditions can be optimized for the desired electrical characteristics of the semiconductor devices independent of each other – e.g., a low-temperature regime for memory cells and a high-temperature regime for logic circuits. Subsequently, the semiconductor devices fabricated in different temperature regimes can be brought together such that they can function as a single device as if they are formed in a monolithic substrate. In some embodiments, the semiconductor devices can be brought together (e.g., bonded, attached) at the wafer level (e.g., wafer-to-wafer bonding), at the die level (e.g., die-to-die bonding), or at a mixed level (e.g., die-to-wafer bonding). In some embodiments, a direct bonding scheme is used to combine two or more semiconductor dies.

The direct bonding scheme includes individual conductive components (e.g., copper pads, conductive pads, bond pads) of a first semiconductor die (or a first wafer including the first semiconductor die) aligned and directly bonded to corresponding one of conductive components of a second semiconductor die (or a second wafer including the second semiconductor die). Further, a dielectric material surrounding each of the conductive components of the first semiconductor die can be directly bonded to another dielectric material surrounding each of the conductive components of the second semiconductor die. In other words, the bonding interface includes two or more dissimilar materials of the first semiconductor die directly bonded to corresponding materials of the second semiconductor die (e.g., between dielectric materials, between conductive materials) to form interconnects and surrounding dielectric layers. As such, the direct bonding scheme may also be referred to a combination bonding scheme, a hybrid bonding scheme, or the like.

In some embodiments, the conductive materials include copper (or other suitable conductive materials or metals, such as tungsten) as a primary constituent, and the dielectric materials include silicon oxides (e.g., SiO₂), silicon nitrides (e.g., Si₃N₄), silicon carbon nitrides (e.g., SiCN), silicon carbonates (e.g., SiCO), or the like. During the direct bonding process, the dielectric materials of the first and second semiconductor dies (or the first and second wafers including the first and second semiconductor dies) are brought together such that the dielectric materials adhere to each other and hermetically seal the conductive components aligned to each other.

Subsequently, the semiconductor dies (or the semiconductor wafers) are annealed at an elevated temperature (e.g., post bond annealing) such that the conductive materials of the conductive components can expand – e.g., swell vertically toward the bonding interface at least partially due to the differences in coefficients of thermal expansion (CTE) between the conductive materials and the dielectric materials. Eventually, the conductive materials are conjoined (e.g., fused) to form permanent bonding – e.g., metallurgical bonding. Additionally, the dielectric materials may enhance their bonding strength during the post bond annealing process.

The present technology facilitates forming of structures that join (integrate, combine) two different semiconductor dies (e.g., memory dies and logic dies), which have been fabricated using process steps including at least two different temperature regimes (e.g., a high temperature regime and a low temperature regime), respectively. The combined (conjoined, integrated, stacked) semiconductor dies (e.g., one or more memory dies bonded to a logic die) forms a semiconductor device that includes some shared circuits and/or components between them, as well as unique memory cells and analog and digital circuits that are separately fabricated in two different wafers and process steps. In some embodiments, the resulting semiconductor device performs artificial intelligence (AI) tasks. In some embodiments, the resulting semiconductor device forms an artificial neural network (or a portion thereof) including artificial synapses of artificial neurons included in the memory dies supported by logic functions performed by the logic dies. In some cases, the logic die may perform various analog or digital operations, such as summation, multiplication, comparison, or a combination thereof.

Moreover, the present technology is expected to improve the time it takes to move data back-and-forth between the memory cells and the logic die in view of the direct bonding scheme that reduces distance between them, thereby improving performance and power use of the resulting semiconductor device. Additionally, or alternatively, the resulting semiconductor devices are expected to improve form factors of the semiconductor die assemblies including them enabling new applications and improving efficiency.

As used herein, the terms “front,” “back,” “vertical,” “lateral,” “down,” “up,” “top,” “bottom,” “upper,” and “lower” can refer to relative directions or positions of features in the semiconductor device assemblies in view of the orientation shown in the Figures. For example, “upper” or “uppermost” can refer to a feature positioned closer to the top of a page than another feature. These terms, however, should be construed broadly to include semiconductor devices having other orientations. Unless stated otherwise, terms such as “first” and “second” are used to arbitrarily distinguish between the elements such terms describe. Thus, these terms are not necessarily intended to indicate temporal or other prioritization of such elements.

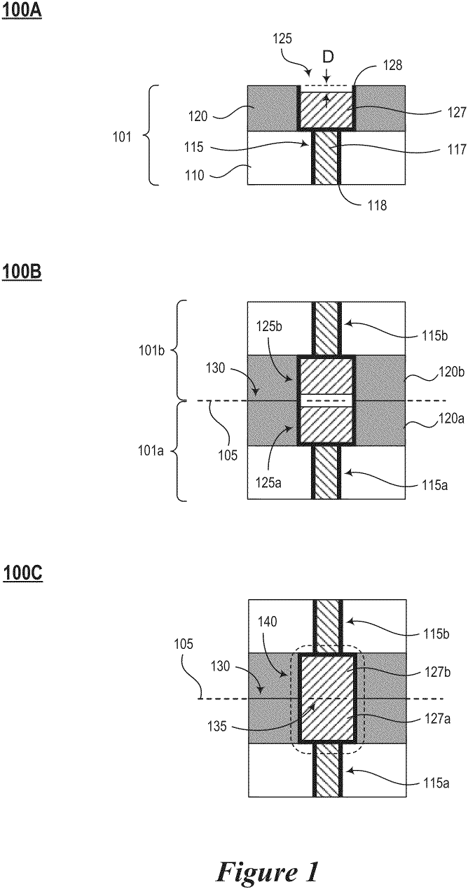

FIG. 1 including diagrams 100A through 100C illustrates various stages of process steps for direct bonding schemes. Diagram 100A illustrates a portion of a semiconductor die 101 with a substrate 110 having integrated circuitry (not shown) and a through-substrate via (TSV) 115 coupled with the integrated circuitry. In some embodiments, the TSV 115 includes a first conductive material 117 (e.g., tungsten) and a conductive barrier layer 118 (e.g., TiN). The semiconductor die 101 also includes a conductive pad 125 (which may also be referred to as a bond pad) formed in a dielectric layer 120 (e.g., silicon oxides, silicon nitrides, silicon carbon nitrides, silicon carbonates, or a combination thereof). The conductive pad 125 is electrically connected to the TSV 115 (and to the integrated circuitry through the TSV 115). In some embodiments, the conductive pad 125 includes a second conductive material 127 (e.g., copper) and another conductive barrier layer 128 (e.g., TaN).

The conductive pad 125 depicted in diagram 100A includes a surface recessed by a depth D with respect to the surface of the dielectric layer 120. In some embodiments, CMP process steps are used to form the conductive pad 125, and the recess may be a result of the CMP process. For example, the recess may be formed during over-polishing steps that remove excessive conductive material 127 on the surface of the dielectric layer 120. Additionally, or alternatively, the amount of recess (e.g., the recess depth D) may be targeted to ensure the surface of the conductive pad 125 not to protrude above the surface of the dielectric layer 120 – e.g., to avoid such protruded conductive pads 125 interfering with the bonding process described with reference to Diagram 100B. Further, the amount of recess may be targeted to be within a certain range such that the conductive materials 127 can form an interconnect 140 without compromising the bonding integrity as described with reference to Diagram 100C.

Diagram 100B illustrates two semiconductor dies 101a and 101b (or two wafers including the semiconductor dies 101a and 101b) that are attached together such that dielectric materials of the top semiconductor die 101b and bottom semiconductor die 101a adhere to each other to form dielectric-to-dielectric bonding 130 at the bonding interface 105 (which may be referred to as a bond line). In some embodiments, the dielectric surfaces are activated (e.g., using a plasma treatment process) to facilitate the bonding of the dielectric surfaces. Also, conductive pads (e.g., the top conductive pad 125b and the bottom conductive pad 125a) of the top and bottom semiconductor dies 101a and 101b are aligned to face each other but may not be connected to each other due to the recessed surfaces of the conductive pads 125a/b.

Diagram 100C illustrates that the bonded dies/wafers are annealed in an elevated temperature (e.g., around 400° C.) such that the conductive materials of the top and bottom conductive pads 125a/b may expand toward each other in response to receiving thermal energy during the post bond annealing process (e.g., due to the mismatch in CTEs between the conductive materials and the dielectric materials) within an open space defined by the recess surfaces and the dielectric material surrounding the conductive pads 125a/b. When the surfaces of the top and bottom conductive materials are in contact, the conductive materials are conjoined (e.g., via atomic migration (intermixing, diffusion) from one conductive material to another conductive material) to form metal-to-metal bonding 135 – e.g., metallurgical bonding, permanent bonding. Once the metallurgical bonding is formed between the conductive pads 125a/b (thus, forming the interconnect 140), the conductive materials do not separate (or sever) when the bonded dies/wafers are brought to the ambient temperature or operating temperatures of the semiconductor die assemblies. In this manner, the bonding interface 105 includes the dielectric-to-dielectric bonding 130 and the metal-to-metal bonding 135.

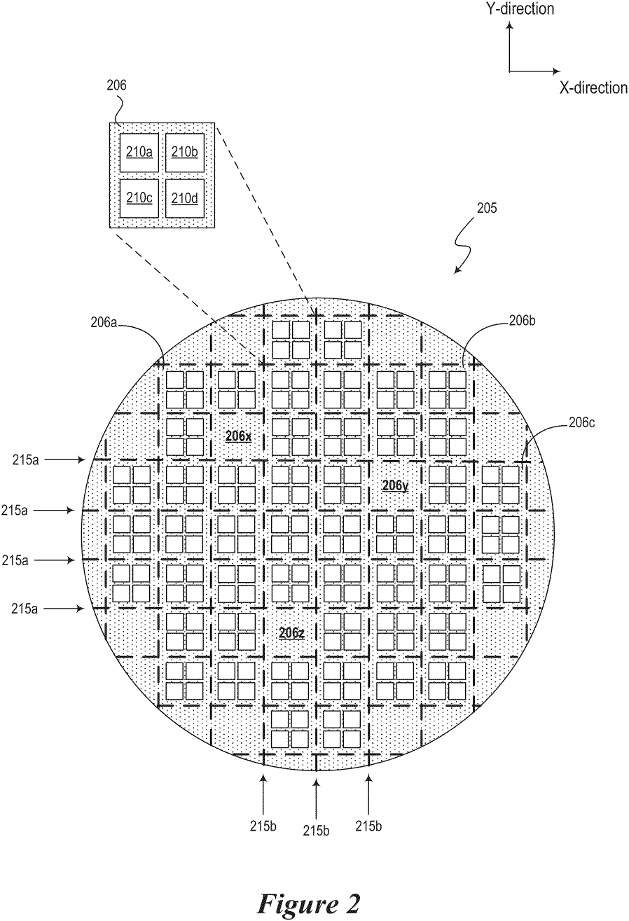

FIG. 2 is a diagram of a substrate 205 carrying semiconductor dies 210 in accordance with embodiments of the present technology. In some embodiments, the substrate 205 may be a semiconductor wafer including semiconductor dies 206 (some of which are also identified individually as semiconductor dies 206a-c and semiconductor dies 206x-z) configured to perform various logic functions. As such, the semiconductor dies 206 may be referred to as logic dies and the substrate 205 may be referred to as a logic wafer. As shown in FIG. 2, one or more semiconductor dies 210 can be attached to individual semiconductor dies 206 – e.g., four (4) semiconductor dies 210 (also identified individually as 210a-d) bonded to a semiconductor die 206. In some embodiments, individual semiconductor dies 206 are tested such that fully functional semiconductor dies 206 (which may be referred to as known good dies) can be identified, to which the semiconductor dies 210 are attached. For example, the semiconductor dies 206x-z do not have semiconductor dies 210 attached as they did not pass the test – e.g., known bad dies.

The substrate 205 carrying the semiconductor dies 210 attached thereto may be referred to as a reconstituted wafer in view of the singulated, individual semiconductor dies 210 that are aligned and attached to corresponding semiconductor dies 206. The scheme of attaching singulated semiconductor dies (e.g., semiconductor dies 210) to a wafer (e.g., the logic wafer 205) may be referred to as a chips-on-wafer (COW) scheme.

In some embodiments, the semiconductor dies 210 are different types of semiconductor dies (e.g., memory dies, DRAM dies, NAND memory dies) than the semiconductor dies 206 (e.g., logic dies). The semiconductor dies 206 can be configured to exchange electrical signals with the semiconductor dies 210 and with higher level circuitry (e.g., a host device external to the semiconductor device assembly) coupled with the semiconductor dies 206 – e.g., through bonding wires, balls of a ball-grid array (BGA). In this regard, the semiconductor dies 210 bonded to the semiconductor dies 206 receive power and communicates signals through the semiconductor dies 206.

Each semiconductor die 210 has a front side, which may be referred to as an active side of the semiconductor die, including various structures such as memory arrays, conductive traces, contacts/vias, integrated circuits (e.g., digital circuitry) coupled to the memory arrays, and bond pads. Similarly, each semiconductor die 206 has a front side including various structures such as integrated circuits (e.g., analog circuitry), conductive traces, contacts/vias, and bond pads. In some embodiments, the front sides of the semiconductor die 210 and the semiconductor die 210 faces each other. Further, as described in more detail herein, the front side of the semiconductor die 210 can be directly bonded to the front side of the semiconductor die 210 – e.g., using the direct bonding scheme described with reference to FIG. 1.

The semiconductor dies 206 (with semiconductor dies 210 attached thereto) can be configured to couple with external circuitry (e.g., other processors or semiconductor devices) or higher level circuitry (e.g., a host device, a controller). In some embodiments, the bond pads on the front side of the semiconductor dies 206 can be connect to bonding wires or balls of BGA. In some embodiments, the semiconductor dies 206 include through-substrate vias (TSVs) extending through the semiconductor die 206. The TSVs can be configured to connect the bond pads (or other structures) on the front side of the semiconductor dies 206 to bond pads on the back side of the semiconductor dies 206, which can be further connected to balls of BGA.

In some embodiments, an encapsulating material (e.g., mold compound materials, epoxy molding compounds (EMC)) can be disposed over the substrate 205 after attaching (e.g., directly bonding) the semiconductor dies 210 to individual semiconductor dies 206. As a result, the semiconductor dies 210 may be immersed in the encapsulating material. Subsequently, the encapsulating material can be cured at an elevated temperature to harden the encapsulating material so as to provide protection for the semiconductor dies 210 (and the semiconductor dies 206). Excess encapsulating material above the semiconductor dies may be removed using a grinding process step. The process steps to provide protection for the semiconductor dies using the encapsulating material may be referred to as a molding process.

Also depicted in FIG. 2, the substrate 205 includes scribe lines 215 (which may be referred to as dicing lanes, cutting lines, or the like) between the semiconductor dies 206 – e.g., horizontal scribe lines 215a along the x-direction and vertical scribe lines 215b along the y-direction. Singulation process steps can be carried out to separate (e.g., sever, singulate) individual semiconductor die assemblies (e.g., a semiconductor die 206 with one or more semiconductor dies 210 attached thereto) from the substrate 205 by cutting the substrate 205 along the scribe lines 215.

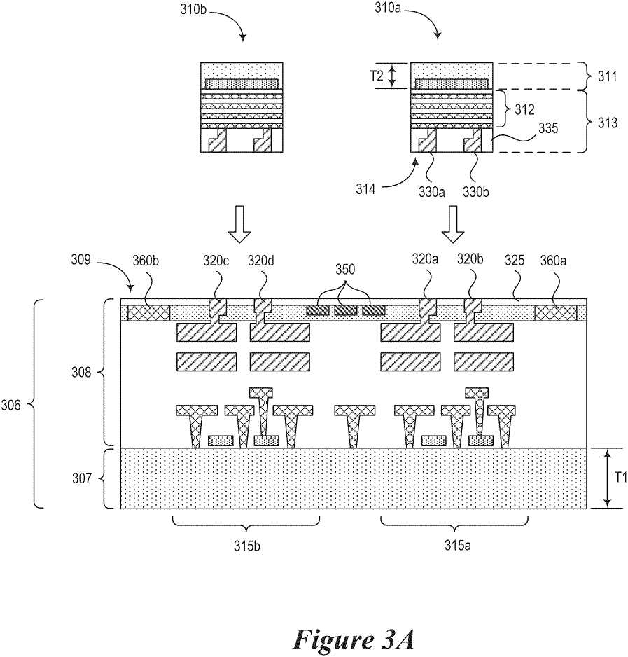

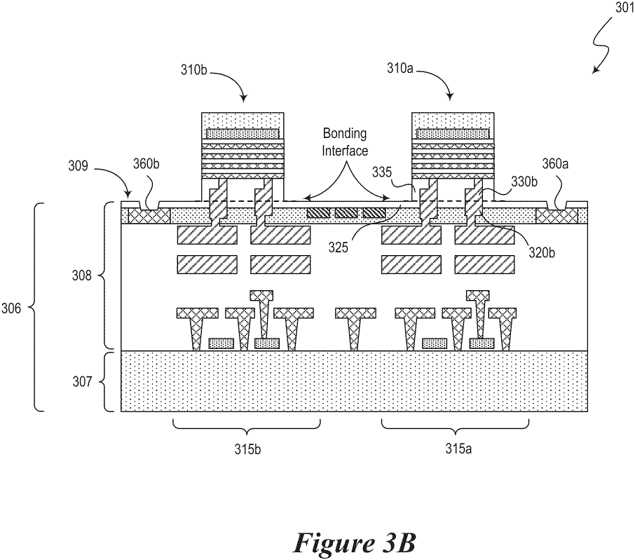

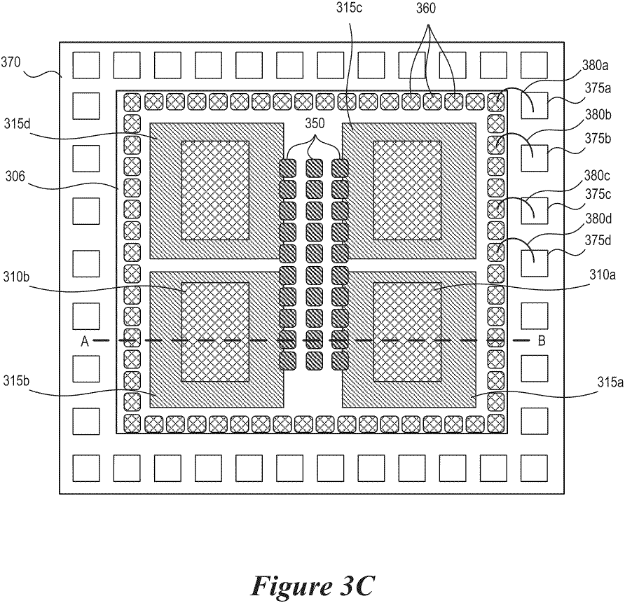

FIGS. 3A through 3C illustrate example schematic diagrams depicting various stages of forming semiconductor die assemblies in accordance with embodiments of the present technology. FIG. 3A shows a first semiconductor die 306 (which may be an example of or include aspects of the semiconductor die 206) or a portion of a semiconductor wafer (e.g., the substrate 205) including the first semiconductor die 306. The first semiconductor die 306 includes a semiconductor substrate 307 (e.g., silicon substrate) with a thickness T1 and a dielectric layer 308 above the semiconductor substrate 307. The semiconductor substrate 307 and the die-layer 308 includes various structures that can be connected together to form integrated circuits of the first semiconductor die 306. For example, semiconductor junctions (e.g., sources and drains of MOS transistors, wells) can be formed in the semiconductor substrate 307 while gates of the MOS transistors, contacts, interconnect structures can be formed in the dielectric layer 308.

In some embodiments, the first semiconductor die 306 includes one or more circuit blocks 315 (also identified individually as circuit blocks 351a/b), each including the various structures generated in the semiconductor substrate 307 and the die-layer 308. Each of the circuit blocks 315 may be configured to perform same functions - e.g., analog functions, digital functions, digital-to-analog (DAC) functions, analog-to-digital (ADC) functions. Moreover, each of the circuit blocks 315 includes conductive components 320 (also identified individually as conductive components 320a-d) on a front side 309 of the first semiconductor die 306. The conductive components 320 (e.g., bond pads, copper pads) are coupled with the various structures of the circuit blocks 315.

The first semiconductor die 306 may include probe pads 350 configured to test functionality of the circuit blocks 315. For example, the probe pads 350 can be used to identify “good” first semiconductor dies 306 (e.g., fully functional first semiconductor dies 306 satisfying specifications for the first semiconductor dies 306). Subsequent process steps (e.g., die-attaching process) can be skipped for known “bad” first semiconductor dies 306 (e.g., the semiconductor die 206x-z depicted in FIG. 2). Thereafter, the probe pads 350 are covered with a dielectric layer 325, which may be planarized to provide a uniform surface on the front side 309 during the subsequent process steps (e.g., direct bonding process steps). Additionally, or alternatively, the first semiconductor die 306 may include bond pads 360 (also identified individually as bond pads 360a/b). The bond pads 360 are coupled with the circuit blocks 315 (i.e., various structures of the circuit blocks 315). At this stage of the process flow, the bond pads 360 may be covered with the dielectric layer 325.

Also illustrated in FIG. 3A are second semiconductor dies 310 (also identified individually as second semiconductor dies 310a/b). The second semiconductor die 310 includes a semiconductor substrate 311 (e.g., silicon substrate) with a thickness T2 and a dielectric layer 313 above the semiconductor substrate 311 (the second semiconductor dies 310a/b are depicted to have been flipped upside-down as front sides 314 of the second semiconductor dies 310a/b face downward as shown in FIG. 3A). In some embodiments, the thickness T2 of the semiconductor substrate 311 is different than the thickness T1 of the semiconductor substrate 307. For example, the thickness T2 may be less than the thickness T1.

The semiconductor substrate 311 and the die-layer 313 includes various structures that can be connected together to form integrated circuits (e.g., memory cells and circuits associated with the memory cells) of the second semiconductor die 310. For example, semiconductor junctions (e.g., sources and drains of MOS transistors) can be formed in the semiconductor substrate 311 while gates of the MOS transistors, contacts, interconnect structures, and an array of memory cells 312 (e.g., 3D NAND structures, cell capacitors of DRAM cells) can be formed in the die-layer 313. Moreover, the second semiconductor die 310 includes conductive components 330 (also identified individually as conductive components 330a-d) on the front side 314 of the first semiconductor die 310. The conductive components 330 (e.g., bond pads, copper pads) are coupled with the array of memory cells 312. In some embodiments, the semiconductor dies 310 includes the array of memory cells 312 with the conductive components 330 only – i.e., the semiconductor substrate 311 is omitted (removed).

The second semiconductor dies 310 can be attached to corresponding circuit blocks 315 of the first semiconductor die 306 (or the wafer including the first semiconductor die 306). In some embodiments, attaching the second semiconductor dies 310 to corresponding circuit blocks 315 can be accomplished in accordance with the direct bonding scheme described with reference to FIG. 1. In this regard, the second semiconductor dies 310 can be arranged over corresponding circuit blocks 315 such that the front side 309 of the first semiconductor die 306 and the front sides 314 of the second semiconductor dies 310 face each other. Further, each of the first conductive components 320 of the circuit blocks 315 is aligned to the corresponding one of the second conductive components 330.

Thereafter, the front side 314 of the second semiconductor die 310 can be brought to contact the front side 309 of the first semiconductor die 306 as indicated by the arrows. As a result, the dielectric layer 335 surrounding the conductive components 330 can be in direct contact with the dielectric layer 325 surrounding the conductive components 320 – e.g., forming a bonding interface (or a bond line). In some embodiments, the surface of the front side 309 and/or the surface of the front side 314 can be treated with a plasma process (e.g., plasma activation) to facilitate the dielectric bonding between the dielectric layer 335 and the dielectric layer 325. The conductive components 330 may not be in contact with the conductive components 320 at this stage due to the recess with respect to the bonding interface as described above with reference to FIG. 1.

Subsequently, the first semiconductor die 306 with the second semiconductor dies 310 attached thereto (or the wafer including the first semiconductor die 306 with the second semiconductor dies 310 attached thereto) can be annealed at an elevated temperature – e.g., the post-bond annealing step to conjoin the conductive components 330 with the conductive components 320. As a result, each of the first conductive components 320 of the circuit blocks 315 is conjoined to a corresponding one of the second conductive components 330 of the second semiconductor dies 310 at the bonding interface defined by the front side 309 of the first semiconductor die 306 and the front side 314 of the second semiconductor dies 310.

FIG. 3B shows the first semiconductor die 306 (or a portion of the semiconductor wafer including the first semiconductor die 306) with the second semiconductor dies 310a/b attached (directly bonded) thereto after completing the direct bonding process. In some embodiments, the second semiconductor dies 310a/b are spaced apart by at least 80 µm or greater. The space between the second semiconductor dies 310a/b may be determined based on a process capability to precisely position each second semiconductor die 310 to the underlying structure (e.g., the circuit blocks 315) or a process capability to fill the space with a filler material.

As shown in FIG. 3B, each of the first conductive components 320 (e.g., the conductive component 320b) is conjoined to a corresponding one of the second conductive components 330 (e.g., the conductive component 330b) at the bonding interface defined by the front side 309 of the first semiconductor die 306 and the front sides 314 of the second semiconductor dies 310. Further, at the bonding interface, the dielectric layer 325 surrounding each of the first conductive components 320 is directly bonded to the dielectric layer 335 surrounding each of the second conductive components 330.

After completing the direct bonding process, portions of the dielectric layer 325 can be removed to expose the bond pads 360. As shown in FIG. 3B, an edge of the first semiconductor die 306 extends past a corresponding edge of at least one second semiconductor dies 310 such that a portion of the front side 309 of the first semiconductor die 306 is exposed, where the portion includes the bond pads 360 that are coupled with the circuit blocks 315. Individual first semiconductor dies 306 (with the second semiconductor dies 310 directly bonded thereto) can be singulated to generate the semiconductor device 301 that may operate as a single semiconductor device. As the second conductive components 330 are conjoined with the first conductive components 320, which are further connected to the bond pads 360, the second semiconductor dies 310 are connected to the power and transmit/receive electrical signals through the bond pads 360.

FIG. 3C shows a top-down view of the semiconductor device 301 attached to a package substrate 370. The cross-sectional diagram of the semiconductor device 301 illustrated in FIG. 3B corresponds to the cross-section along the line AB. The package substrate 370 includes substrate bond pads 375 (some of which are also identified individually as 375a-d). The front side 309 of the first semiconductor die 306 faces away from the package substrate 370. The bond pads 360 of the semiconductor device 301 can be connected to corresponding substrate bond pads 375 using bonding wires 380 (some of which are depicted and also identified individually as bonding wires 380a-d) as depicted in FIG. 3C.

In some embodiments, the first semiconductor die 306 (e.g., the circuit blocks 315a-d) performs various logic operations. Such logic operations may include digital operations, analog operations, ADC operations, DAC operations, or the like. As such, the first semiconductor die 306 may be referred to as a logic die. The second semiconductor die 310 may be referred to as memory dies (or memory chiplets) in view of the array of memory cells 312. In some embodiments, the semiconductor device 301 including the logic die 306 and the memory dies 310 can be configured to perform various tasks associated with artificial intelligence. In some embodiments, the semiconductor device 301 forms an artificial neural network (or a portion thereof) including artificial synapses of artificial neurons emulated in the memory dies 310, which is supported by the logic functions performed by the logic die 306 (e.g., the circuit blocks 315). In some cases, the logic die 306 may perform various analog and/or digital operations for the artificial synapses, such as summation, multiplication, comparison, or a combination thereof.

As the present technology described herein facilitates combining at least two different semiconductor dies having at least two different primary functions (e.g., logic function and data/information storage function) after completing their fabrication process, process steps to fabricate each semiconductor dies can be optimized independent of each other. For example, the process steps fabricating the logic die 306 (e.g., the circuit blocks 315) can be optimized independent of the process steps fabricating the memory dies 310 (e.g., the array of memory cells 312). In some cases, some of the process steps may be mutually exclusive – e.g., certain process steps optimized for fabricating the logic die 306 (or the circuit blocks 315) may deteriorate or destroy the functionality of memory dies 310 or vice versa.

In some embodiments, the circuit blocks 315 includes a first structure generated using a first process at a first temperature. For example, the circuit blocks 315 include junctions with a junction depth of 0.1 micrometers (µm) or greater, which may require thermally annealing the logic die 306 (or the logic wafer including the logic dies 306) at an elevated temperature (e.g., 900° C., 1000° C., or even higher temperature). Additionally, or alternatively, the circuit blocks 315 may include a silicide layer formed on certain semiconductor regions (e.g., poly-silicon gates, source/drain regions) for reducing resistance, which may require process temperature reaching approximately 600° C. or greater. In some cases, the circuit blocks 315 may include an epitaxial layer formed at temperature around 1200° C. In some embodiments, the circuit blocks 315 include high-power analog circuitry.

In some embodiments, the memory dies 310 (e.g., the array of memory cells 312) includes a second structure generated using a second process at a second temperature that is less than the first temperature. For example, the memory cells of the array may include a data storage structure including a chalcogenide compound formed at around 400° C. or a dielectric material with a dielectric constant greater than that of silicon dioxide (SiO₂). In some embodiments, the first temperature renders the memory cells of the array non-functional if the memory cells are subject to the first temperature.

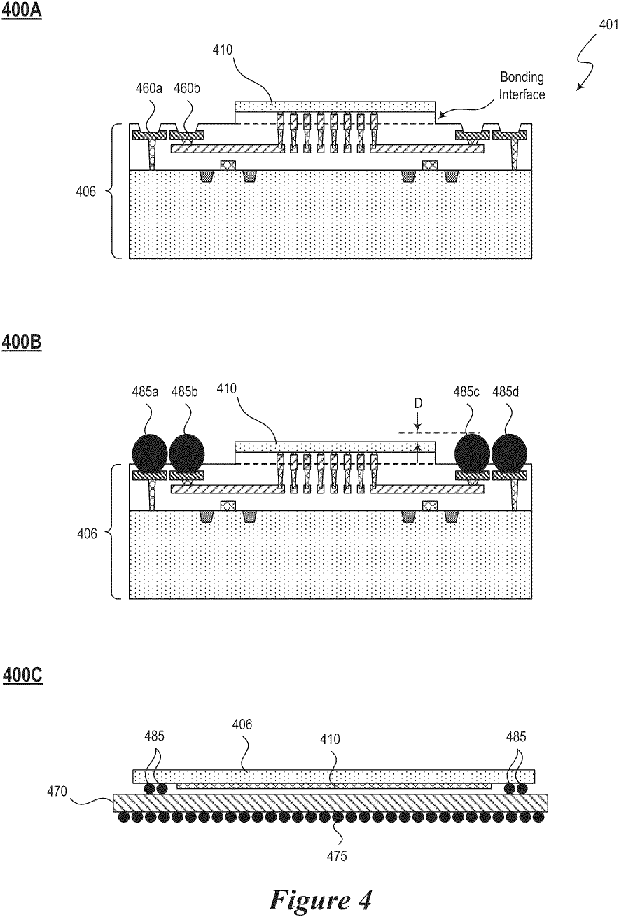

FIG. 4 illustrates schematic diagrams 400A through 400C depicting various stages of forming semiconductor die assemblies in accordance with embodiments of the present technology. Diagram 400A illustrates a first semiconductor die 406 (which may be an example of or include aspects of the semiconductor die 206 or the semiconductor die 306) or a portion of a semiconductor wafer (e.g., the substrate 205) including the first semiconductor die 406. Moreover, a second semiconductor die 410 (which may be an example of or include aspects of the semiconductor die 210 or the semiconductor die 310) is directly bonded to the first semiconductor die 406 at the bonding interface.

The resulting semiconductor device 401 (i.e., the first semiconductor die 406 with the second semiconductor die 410 bonded thereto) may be an example of or include aspects of the semiconductor device 301 described with reference to FIG. 3B. In some embodiments, the first semiconductor die 406 is a logic die (e.g., the logic die 306) and the second semiconductor die 410 is a memory die (e.g., the memory die 310). The first semiconductor die 406 includes bond pads 460 (also identified individually as 460a/b, which may be examples of or include aspects of bond pads 360) coupled to integrated circuits (e.g., logic circuits) of the first semiconductor die 406 that is further connected to the second semiconductor die 410 (e.g., array of memory cells of the second semiconductor die 410). As such, the bond pads 460 can be regarded as terminals for the semiconductor device 401, which provide power and electrical signal for both the first semiconductor die 406 and the second semiconductor die 410.

Diagram 400B illustrates that balls 485 (also identified individually as balls 485a- d) of BGA are formed on the bond pads 460. As such, the second semiconductor die 410 (e.g., a memory chiplet) can be surrounded by the balls 485. Moreover, the height of the balls 485 extended above the bonding interface is greater than the height of the second semiconductor die 410 as denoted by the distance D depicted in Diagram 400B.

Diagram 400C illustrates that the semiconductor device 401 is flipped and attached to a package substrate 470 through the balls 485. As the height of the balls 485 extended above the bonding interface is greater than that of the second semiconductor die 410, the second semiconductor die 410 may not contact the package substrate 470. The package substrate 470 includes terminals 475 such that the semiconductor device 401 including the first semiconductor die 406 and the second semiconductor die 410 can be coupled to components (e.g., a host device) external to the semiconductor device 401 through the terminals 475.

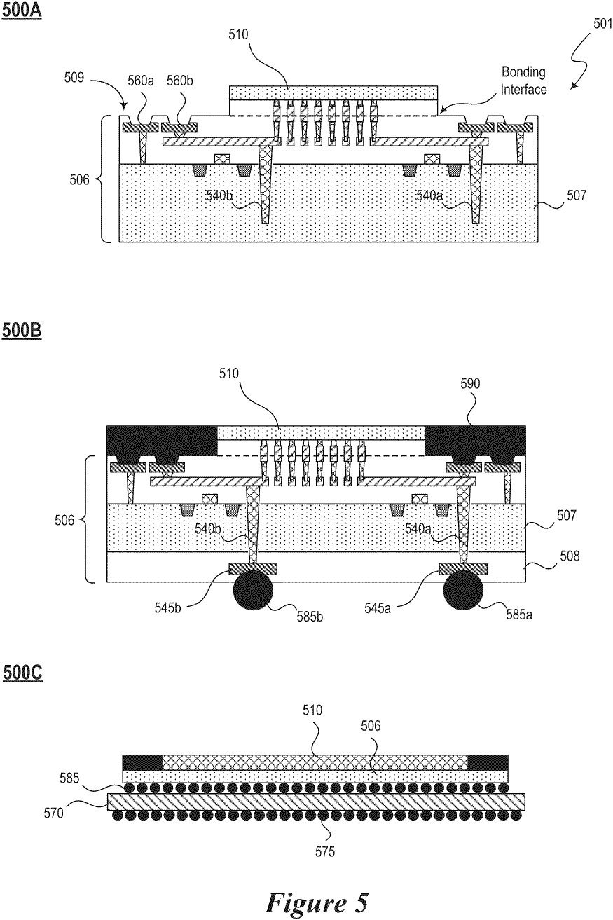

FIG. 5 illustrates schematic diagrams 500A through 500C depicting various stages of forming semiconductor die assemblies in accordance with embodiments of the present technology. Diagram 500A illustrates a first semiconductor die 506 (which may be an example of or include aspects of the semiconductor die 406) or a portion of a semiconductor wafer (e.g., the substrate 205) including the first semiconductor die 506. Moreover, a second semiconductor die 510 (which may be an example of or include aspects of the semiconductor die 410) is directly bonded to the first semiconductor die 506 at the bonding interface. Moreover, the first semiconductor die 506 includes through-substrate vias (TSVs) 540 (also identified individually as TSVs 540a/b). The TSVs 540 can be connected to bond pads 560 (also identified individually as 560a/b, which may be examples of or include aspects of the bond pads 460) on the front side 509 of the first semiconductor die 506 and extend into the semiconductor substrate 507 of the first semiconductor die 506.

The resulting semiconductor device 501 (i.e., the first semiconductor die 506 with the second semiconductor die 510 bonded thereto) may be an example of or include aspects of the semiconductor device 401 (or the semiconductor device 301 described with reference to FIG. 3B). In some embodiments, the first semiconductor die 506 is a logic die (e.g., the logic die 306) and the second semiconductor die 510 is a memory die (e.g., the memory die 310). The first semiconductor die 506 includes bond pads 560 (also identified individually as 560a/b, which may be examples of or include aspects of bond pads 360) coupled to integrated circuits (e.g., logic circuits) of the first semiconductor die 506 that is further connected to the second semiconductor die 510 (e.g., array of memory cells of the second semiconductor die 510). In some embodiments, the semiconductor device 501 can be tested using the bond pads 560 after attaching (bonding) the second semiconductor die 510 to the first semiconductor die 506. In some embodiments, the first semiconductor die 506 can be tested using the bond pads 560 before attaching (bonding) the second semiconductor die 510 to the first semiconductor die 506 – e.g., to confirm the first semiconductor die 506 is a “good” die.

Diagram 500B illustrates that the bond pads 560 are covered with an encapsulant 590 – e.g., after completing the molding process described with reference to FIG. 2. Moreover, the semiconductor substrate 507 has been thinned from the back side of the first semiconductor die 506 (or from the back side of the semiconductor wafer including the first semiconductor die 506) to expose portions of the TSVs 540. Thereafter, a dielectric layer 508 and conductive pads 545 (also identified individually as conductive pads 545a/b) are formed on the back side such that the TSVs 540 can connect the bond pads 560 on the front side 509 to the conductive pads 545 on the back side, which is opposite to the front side 509. Moreover, terminals 585 (also identified individually as terminals 585a/b) can be formed on the conductive pads 545. As such, the terminals 585 can be regarded as terminals for the semiconductor device 501, which provide power and electrical signal for both the first semiconductor die 506 and the second semiconductor die 510.

Diagram 500C illustrates that the semiconductor device 501 is attached to a package substrate 570 through the terminals 585. The package substrate 570 includes terminals 575 such that the semiconductor device 501 including the first semiconductor die 506 and the second semiconductor die 510 can be coupled to components (e.g., a host device) external to the semiconductor device 501 through the terminals 575.

In some embodiments, the first semiconductor die 506 does not include the TSVs 540 prior to the bonding operation. In such embodiments, the TSVs 540 can be formed after the bonding operation – e.g., after thinning the wafer including the first semiconductor die 506 with the second semiconductor die 510 bonded thereto (e.g., the CoW wafer) from its back side. In this manner, the TSVs 540 can be coupled to the bond pads 560 on the front side 509 of the first semiconductor die 506. Thereafter, the dielectric layer 508 and the conductive pads 545 can be formed on the back side such that the TSVs 540 can connect the bond pads 560 on the front side 509 to the conductive pads 545.

Although the present technology is described herein with schematic diagrams illustrating semiconductor device assemblies including one, two, or four second semiconductor dies (e.g., memory dies) directly bonded to a first semiconductor die (e.g., a logic die), it should be understood that the principles of the present technology is not limited thereto. For example, a semiconductor device assembly in accordance with the present technology may include a different quantity of memory dies (e.g., six, eight, or even greater) directly bonded to a logic die. Further, the principles of the present technology is not limited to any particular types of memory cells. For example, the memory dies can include a variety of memory cells, such as DRAM (or other volatile memory cells), PCM, or NAND (or other nonvolatile memory cells.

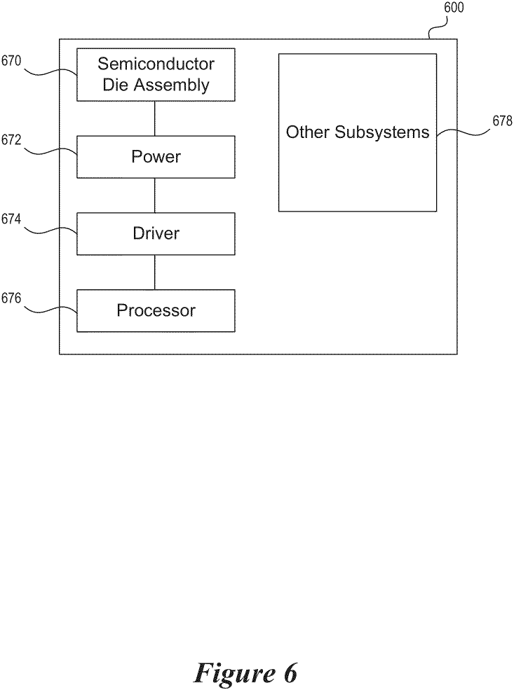

FIG. 6 is a block diagram schematically illustrating a system 600 including a semiconductor die assembly in accordance with embodiments of the present technology. The system 600 can include a semiconductor device assembly 670, a power source 672, a driver 674, a processor 676, and/or other subsystems or components 678. The semiconductor device assembly 670 can be incorporated into any of a myriad of larger and/or more complex systems, a representative example of which is the system 600 shown schematically in FIG. 6. The semiconductor die assembly described with reference to FIGS. 3A-3C, 4, and 5 may be included in the semiconductor device assembly 670 of the system 600.

The semiconductor device assembly 670 can have features generally similar to the semiconductor die assembly described herein with reference to FIGS. 3A-3C, 4, and 5. For example, the semiconductor device assembly 670 may include a logic die including one or more circuit blocks, where each of the one or more circuit blocks includes a plurality of first conductive pads on a front side of the logic die, one or more memory dies that are each bonded to a corresponding circuit block of the logic die, where each of the memory dies includes an array of Not-AND (NAND) memory cells and a plurality of second conductive pads on a front side of the memory die, the plurality of second conductive pads coupled to the array of NAND memory cells. Moreover, each of the first conductive pads is conjoined to a corresponding one of the second conductive pads at a bonding interface defined by the front side of the logic die and the front sides of the one or more memory dies, each of the one or more circuit blocks of the logic die includes a first structure generated using a first process at a first temperature, and each of the arrays of NAND memory cells of the memory dies includes a second structure generated using a second process at a second temperature that is less than the first temperature.

In some embodiments, each of the arrays of NAND memory cells includes an artificial synapse of an artificial neuron, each of the one or more circuit blocks is configured to perform operations for the artificial neuron, such as summation, multiplication, comparison, or a combination thereof, and the one or more circuit blocks each bonded to corresponding one of the arrays of NAND memory cells form at least a portion of an artificial neural network. In some embodiments, the first temperature renders the NAND memory cells of the array non-functional if the NAND memory cells are subject to the first temperature. In some embodiments, the first structure includes one of a silicide, an epitaxial layer, or a junction with a junction depth greater than 0.1 micrometers (µm), and the second structure includes a dielectric material with a dielectric constant greater than that of silicon dioxide (SiO₂).

The resulting system 600 can perform any of a wide variety of functions, such as memory storage, data processing, and/or other suitable functions. Accordingly, representative systems 600 can include, without limitation, hand-held devices (e.g., mobile phones, tablets, digital readers, and digital audio players), computers, and appliances. Components of the system 600 may be housed in a single unit or distributed over multiple, interconnected units (e.g., through a communications network). The components of the system 600 can also include remote devices and any of a wide variety of computer readable media.

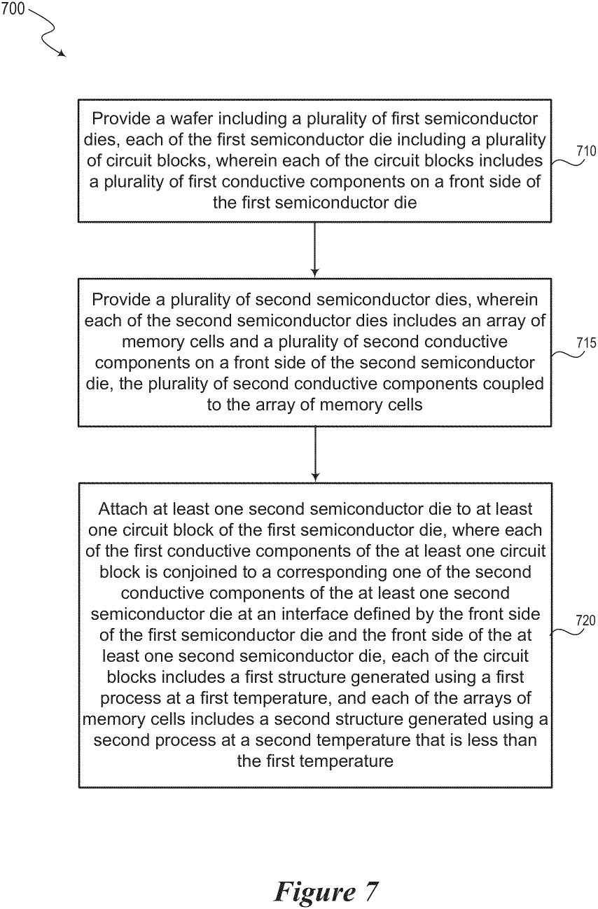

FIG. 7 is a flowchart of a method of forming semiconductor die assemblies in accordance with embodiments of the present technology. The flowchart 700 may include aspects of methods as described with reference to FIGS. 3A-3C through 5.

The method comprises providing a wafer including a plurality of first semiconductor dies, each of the first semiconductor die including a plurality of circuit blocks, wherein each of the circuit blocks includes a plurality of first conductive components on a front side of the first semiconductor die (box 710). The method further comprises providing a plurality of second semiconductor dies, wherein each of the second semiconductor dies includes an array of memory cells and a plurality of second conductive components on a front side of the second semiconductor die, the plurality of second conductive components coupled to the array of memory cells (box 715). The method further comprises attaching at least one second semiconductor die to at least one circuit block of the first semiconductor die, where each of the first conductive components of the at least one circuit block is conjoined to a corresponding one of the second conductive components of the at least one second semiconductor die at an interface defined by the front side of the first semiconductor die and the front side of the at least one second semiconductor die, each of the circuit blocks includes a first structure generated using a first process at a first temperature, and each of the arrays of memory cells includes a second structure generated using a second process at a second temperature that is less than the first temperature (box 720).

In some embodiments, the first temperature renders the memory cells of the array non-functional if the memory cells are subject to the first temperature. In some embodiments, attaching the at least one second semiconductor die to the at least one circuit block of the first semiconductor die includes arranging the at least one second semiconductor die over the at least one circuit block of the first semiconductor die such that the front side of the first semiconductor die and the front side of the at least one second semiconductor die face each other, and each of the first conductive components of the at least one circuit block of the first semiconductor die is aligned to the corresponding one of the second conductive components of the at least one second semiconductor die, and directly bonding the at least one second semiconductor die to the at least one circuit block of the first semiconductor die.

In some embodiments, each of the first semiconductor die includes a set of probe pads, and the method further includes testing functionality of each of the first semiconductor dies using the set of probe pads prior to bonding the at least one second semiconductor die to the at least one circuit block of the first semiconductor die. In some embodiments, the method further includes depositing a dielectric layer over the set of probe pads after testing the functionality of each of the first semiconductor dies, and removing a portion of the dielectric layer such that the dielectric layer includes a planarized surface corresponding to the interface.

It should be noted that the methods described above describe possible implementations, and that the operations and the steps may be rearranged or otherwise modified and that other implementations are possible. Furthermore, embodiments from two or more of the methods may be combined. From the foregoing, it will be appreciated that specific embodiments of the technology have been described herein for purposes of illustration, but that various modifications may be made without deviating from the disclosure. In addition, while in the illustrated embodiments certain features or components have been shown as having certain arrangements or configurations, other arrangements and configurations are possible. Moreover, certain aspects of the present technology described in the context of particular embodiments may also be combined or eliminated in other embodiments.

The devices discussed herein, including a semiconductor device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.” The term “exemplary” used herein means “serving as an example, instance, or illustration,” and not “preferred” or “advantageous over other examples.”

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor die assembly, comprising:
a first semiconductor die including a plurality of circuit blocks, wherein each of the circuit blocks includes a plurality of first conductive components on a front side of the first semiconductor die; and
a plurality of second semiconductor dies that are each bonded to a corresponding circuit block of the first semiconductor die, wherein each of the second semiconductor dies includes an array of memory cells and a plurality of second conductive components on a front side of the second semiconductor die, the plurality of second conductive components coupled to the array of memory cells, wherein:
each of the first conductive components is conjoined to a corresponding one of the second conductive components at a bonding interface defined by the front side of the first semiconductor die and the front sides of the second semiconductor dies;
each of the circuit blocks includes a first structure generated using a first process at a first temperature; and
each of the arrays of memory cells includes a second structure generated using a second process at a second temperature that is less than the first temperature.

2. The semiconductor die assembly of claim 1, wherein the first semiconductor die includes a first semiconductor substrate with a first thickness and each of the second semiconductor dies includes a second semiconductor substrate with a second thickness different than the first thickness.

3. The semiconductor die assembly of claim 1, wherein the first temperature renders the memory cells of the array non-functional if the memory cells are subject to the first temperature.

4. The semiconductor die assembly of claim 1, wherein:
the first structure includes one of a silicide, an epitaxial layer, or a junction with a junction depth greater than 0.1 micrometers (µm); and
the second structure includes one of a chalcogenide compound or a dielectric material with a dielectric constant greater than that of silicon dioxide (SiO₂).

5. The semiconductor die assembly of claim 1, wherein an edge of the first semiconductor die extends past a corresponding edge of at least one second semiconductor die such that a portion of the front side of the first semiconductor die is exposed, the portion including a set of bond pads coupled with the circuit blocks.

6. The semiconductor die assembly of claim 5, wherein power or electrical signals for the array of memory cells are provided through the set of bond pads.

7. The semiconductor die assembly of claim 5, further comprising:
a set of bond wires configured to connect the set of bond pads to a set of substrate bond pads of a substrate to which the first semiconductor die is attached with the front side of the first semiconductor die facing away from the substrate.

8. The semiconductor die assembly of claim 5, further comprising:
a set of ball grids configured to connect the set of bond pads to a set of substrate bond pads of a substrate to which the first semiconductor die is attached with the front side of the first semiconductor die facing the substrate.

9. The semiconductor die assembly of claim 5, wherein the first semiconductor die includes a set of through-substrate vias (TSVs) configured to connect the set of bond pads to a set of ball grids on a back side of the first semiconductor die opposite to the front side.

10. The semiconductor die assembly of claim 1, wherein:
the first semiconductor die includes a set of probe pads configured to test functionality of the plurality of circuit blocks; and
the set of probe pads are covered with a dielectric layer having a planarized surface corresponding to the bonding interface.

11. The semiconductor die assembly of claim 1, wherein:
each of the arrays of memory cells includes an artificial synapse of an artificial neuron;
each of the circuit blocks is configured to perform operations for the artificial neuron, such as summation, multiplication, comparison, or a combination thereof; and
the plurality of circuit blocks that are each bonded to corresponding one of the arrays of memory cells forms an artificial neural network.

12. A method comprising:
providing a wafer including a plurality of first semiconductor dies, each of the first semiconductor die including a plurality of circuit blocks, wherein each of the circuit blocks includes a plurality of first conductive components on a front side of the first semiconductor die;
providing a plurality of second semiconductor dies, wherein each of the second semiconductor dies includes an array of memory cells and a plurality of second conductive components on a front side of the second semiconductor die, the plurality of second conductive components coupled to the array of memory cells; and
attaching at least one second semiconductor die to at least one circuit block of the first semiconductor die, wherein:
each of the first conductive components of the at least one circuit block is conjoined to a corresponding one of the second conductive components of the at least one second semiconductor die at an interface defined by the front side of the first semiconductor die and the front side of the at least one second semiconductor die;
each of the circuit blocks includes a first structure generated using a first process at a first temperature; and
each of the arrays of memory cells includes a second structure generated using a second process at a second temperature that is less than the first temperature.

13. The method of claim 12, wherein the first temperature renders the memory cells of the array non-functional if the memory cells are subject to the first temperature.

14. The method of claim 12, wherein attaching the at least one second semiconductor die to the at least one circuit block of the first semiconductor die includes:
arranging the at least one second semiconductor die over the at least one circuit block of the first semiconductor die such that the front side of the first semiconductor die and the front side of the at least one second semiconductor die face each other, and each of the first conductive components of the at least one circuit block of the first semiconductor die is aligned to the corresponding one of the second conductive components of the at least one second semiconductor die; and
directly bonding the at least one second semiconductor die to the at least one circuit block of the first semiconductor die.

15. The method of claim 12, wherein each of the first semiconductor die includes a set of probe pads, the method further comprising:
testing functionality of each of the first semiconductor dies using the set of probe pads prior to bonding the at least one second semiconductor die to the at least one circuit block of the first semiconductor die.

16. The method of claim 15, further comprising:
depositing a dielectric layer over the set of probe pads after testing the functionality of each of the first semiconductor dies; and
removing a portion of the dielectric layer such that the dielectric layer includes a planarized surface corresponding to the interface.

17. A semiconductor die assembly, comprising:
a logic die including one or more circuit blocks, wherein each of the one or more circuit blocks includes a plurality of first conductive pads on a front side of the logic die; and
one or more memory dies that are each bonded to a corresponding circuit block of the logic die, wherein each of the memory dies includes an array of Not-AND (NAND) memory cells and a plurality of second conductive pads on a front side of the memory die, the plurality of second conductive pads coupled to the array of NAND memory cells, wherein:
each of the first conductive pads is conjoined to a corresponding one of the second conductive pads at a bonding interface defined by the front side of the logic die and the front sides of the one or more memory dies;
each of the one or more circuit blocks of the logic die includes a first structure generated using a first process at a first temperature; and
each of the arrays of NAND memory cells of the memory dies includes a second structure generated using a second process at a second temperature that is less than the first temperature.

18. The semiconductor die assembly of claim 17, wherein:
each of the arrays of NAND memory cells includes an artificial synapse of an artificial neuron;
each of the one or more circuit blocks is configured to perform operations for the artificial neuron, such as summation, multiplication, comparison, or a combination thereof; and
the one or more circuit blocks each bonded to corresponding one of the arrays of NAND memory cells form at least a portion of an artificial neural network.

19. The semiconductor die assembly of claim 17, wherein the first temperature renders the NAND memory cells of the array non-functional if the NAND memory cells are subject to the first temperature.

20. The semiconductor die assembly of claim 17, wherein:
the first structure includes one of a silicide, an epitaxial layer, or a junction with a junction depth greater than 0.1 micrometers (µm); and
the second structure includes a dielectric material with a dielectric constant greater than that of silicon dioxide (SiO₂).
